(19) United States
(12) Patent Application Publication
(10) Pub. No.: US 2026/0075718 A1
(43) Pub. Date: Mar. 12, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Uzou RYU, Toyonaka Osaka (JP)

(21) Appl. No.: 19/063,736

(22) Filed: Feb. 26, 2025

(30) Foreign Application Priority Data
Sep. 12, 2024 (JP) 2024-158089

(51) Int. Cl. H05K 1/18

(52) U.S. Cl. CPC H05K 1/181; H05K 2201/10166; H05K 2201/10174; H05K 2201/2018

(57) ABSTRACT

A semiconductor device of an embodiment includes a circuit board, a base plate, a case, and a concave portion. The circuit board is equipped with semiconductor elements. The base plate supports the circuit board on a support surface. The case is adhered to the base plate at an adhesive region in a normal direction to the support surface. The case surrounds the circuit board. The base plate has a first inclined surface. The first inclined surface is inclined with respect to the support surface. The case has a second inclined surface. The second inclined surface is parallel to the first inclined surface and faces the first inclined surface in the normal direction. The adhesive region is provided on each of the first and second inclined surfaces. The concave portion opens to the outside between the base plate and the case. At least one of the first inclined surface and the second inclined surface is exposed in the concave portion.

### CROSS-REFERENCE TO RELATED APPLICATION

This application is based upon and claims the benefit of priority from Japanese Patent Application No. 2024-158089, filed on Sep. 12, 2024; the entire contents of which are incorporated herein by reference.

### FIELD

Embodiments described herein relate generally to a semiconductor device.

### BACKGROUND

In a semiconductor device such as a power module, a semiconductor is connected onto a base plate having internal wiring, and the device is composed of a resin case having signal terminals and a main circuit, and a filler such as resin that protects the semiconductor.

In the above semiconductor device, since the case is required to be airtight and have a high adhesive strength when the case is attached to the base plate, a process is performed in which an adhesive called a joining agent is applied to the base plate to adhere the base plate and the case. If there is variation in the application position of the adhesive, there is a risk that the adhesive will overflow outward beyond the sides of the base plate and case when the case is adhered. In order to reduce the risk of overflow, it is common to provide a skirt structure that extends from the side surface of the case toward the base plate and covers the side surface of the base plate from the outside. However, in a semiconductor device whose external dimensions are fixed, it is not possible to provide a structure that protrudes from the side surface.

Therefore, a chamfered notch is provided on the inside of the lower end of the side wall of the case, and the overflowing adhesive is accommodated in the notch. Incidentally, if the adhesive application position is shifted inward from the lower end of the case, a gap is formed between the adhesive and the case, and air enters this gap and expands and contracts due to repeated heating during operation of the semiconductor device. Therefore, if the air spreads to the filler inside the case, there is a concern that the filler may peel off to cause reduced reliability. On the other hand, if the adhesive application position is shifted outward from the lower end of the case, there is a concern that the adhesive may overflow outward as described above.

Moreover, since the base plate warps due to heating during reflow, in order to correct the warp, the base plate is warped in advance in the opposite direction to the warp. However, when joining the case to the warped base plate, the gap between the case and the base plate becomes excessively large. As a result, there is a risk of gaps occurring at the adhered areas to cause the filler to leak.

### BRIEF DESCRIPTION OF THE DRAWINGS

FIG. 1 is a plan view of a semiconductor device of an embodiment.

FIG. 2 is a cross-sectional view taken along line A-A of FIG. 1.

FIG. 3 is a cross-sectional view of the semiconductor device of the embodiment.

FIG. 4 is a cross-sectional view taken along line B-B of FIG. 1.

FIG. 5 is a cross-sectional view taken along line B-B of FIG. 1.

FIG. 6 is a cross-sectional view taken along line B-B of FIG. 1.

FIG. 7 is a partially cross-sectional view of a semiconductor device of a second embodiment.

FIG. 8 is a partially cross-sectional view of a semiconductor device of a third embodiment.

FIG. 9 is a partially cross-sectional view of a semiconductor device of a fourth embodiment.

FIG. 10 is a partially cross-sectional view of a semiconductor device of a fifth embodiment.

### DETAILED DESCRIPTION

A semiconductor device of an embodiment includes a circuit board, a base plate, a case, and a concave portion. The circuit board is equipped with semiconductor elements. The base plate supports the circuit board on a support surface. The case is adhered to the base plate at an adhesive region in a normal direction to the support surface. The case surrounds the circuit board. The base plate has a first inclined surface. The first inclined surface is inclined with respect to the support surface. The case has a second inclined surface. The second inclined surface is parallel to the first inclined surface and faces the first inclined surface in the normal direction. The adhesive region is provided on each of the first and second inclined surfaces. The concave portion opens to the outside between the base plate and the case. At least one of the first inclined surface and the second inclined surface is exposed in the concave portion.

Hereinafter, the semiconductor device of the embodiment will be described with reference to the drawings. In the following description, components having the same or similar functions are denoted by the same reference numerals. In addition, duplicate descriptions of those components may be omitted.

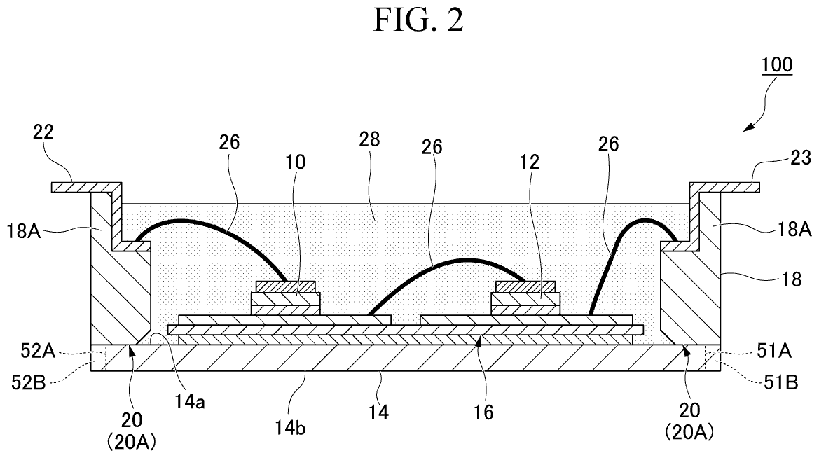

In this specification, in order to indicate the positional relationship of components, etc., the up direction in FIG. 2 may be described as “upper”, and the down direction in the drawings may be described as “lower”. In this specification, the concepts of “upper” and “lower” are not necessarily terms that indicate a relationship with the direction of gravity.

### First Embodiment of Semiconductor Device

Hereinafter, a configuration of a first embodiment of the semiconductor device will be described.

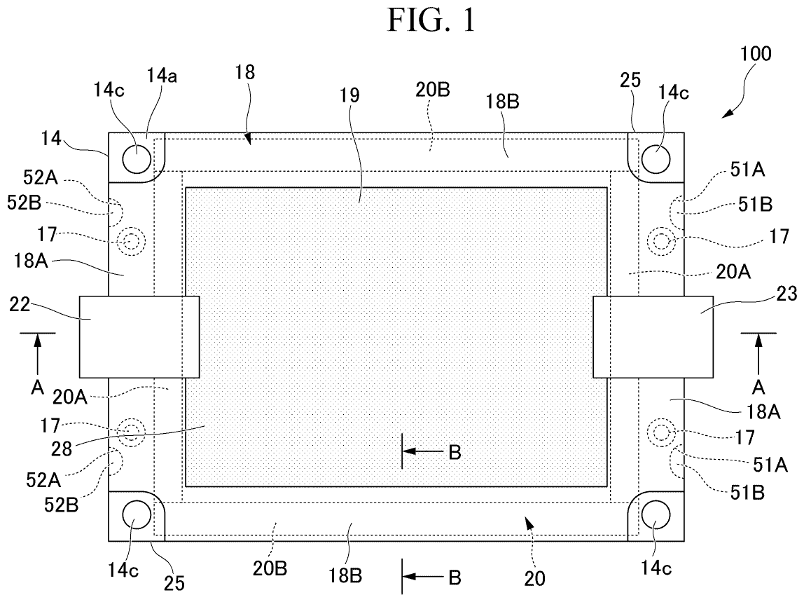

FIG. 1 is a plan view of the semiconductor device of the embodiment. FIG. 2 is a cross-sectional view taken along line A-A of FIG. 1.

A semiconductor device 100 of the embodiment is, for example, a power semiconductor module.

As shown in FIGS. 1 and 2, the semiconductor device 100 includes a first semiconductor element (semiconductor element) 10, a second semiconductor element (semiconductor element) 12, a base plate 14, a circuit board 16, a case 18, an adhesive region 20, a first power terminal 22, a second power terminal 23, a bonding wire 26, and a sealing material 28.

Each of the first semiconductor element 10 and the second semiconductor element 12 is, for example, an Insulated Gate Bipolar Transistor (IGBT), a Metal Oxide Field Effect Transistor (MOSFET), or a diode.

The first semiconductor element 10 and the second semiconductor element 12 are mounted on the circuit board 16. The circuit board 16 is provided on the base plate 14. The circuit board 16 is provided between the base plate 14 and the first semiconductor element 10 and between the base plate 14 and the second semiconductor element 12. The circuit board 16 has a function of electrically isolating (insulating) the base plate 14 from the first semiconductor element 10 and the second semiconductor element 12.

The base plate 14 supports the circuit board 16 on a support surface 14a. The support surface 14a is the upper flat surface of the circuit board 16. As shown in FIG. 1, the base plate 14 has a rectangular shape when viewed in a plan view in a normal direction of the support surface 14a (hereinafter, simply referred to as the normal direction). The base plate 14 is made of, for example, a metal. The base plate 14 is made of, for example, copper. For example, when the semiconductor device 100 is mounted on a product, a heat sink plate (not shown) is connected to the back surface of the base plate 14. The base plate 14 and the heat sink plate are fixed by being fastened together using members inserted into holes 14c formed in the four corners of the base plate 14.

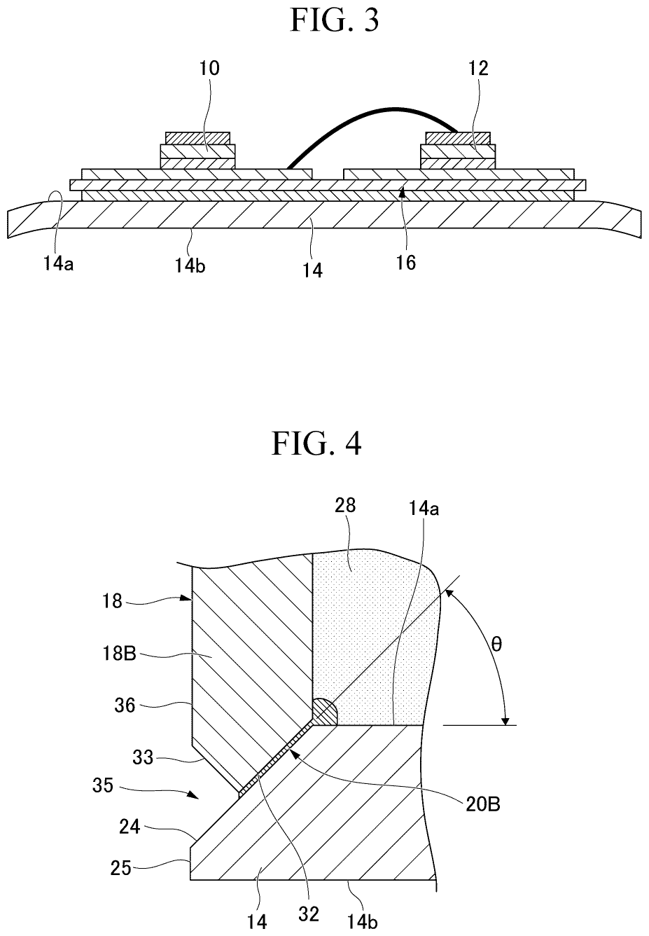

The base plate 14 is warped and deformed due to thermal contraction during assembly of the semiconductor device 100. As shown in FIG. 3, before the case 18 is adhered to the base plate 14, for example, a back surface 14b of the base plate 14, which will be described later, has an upwardly convex shape. In other words, the end of the base plate 14 is curved downward with respect to the center portion. The above shape has been corrected in consideration of deformation due to thermal contraction and the like, in order to improve the adhesion between the back surface 14b of the base plate 14 and the heat sink plate when assembled into the final product.

Furthermore, the back surface 14b of the base plate 14, which will be described later, may have a shape that is convex upward or a shape that is convex downward. The semiconductor device 100 of the embodiment can be applied to both a case in which the back surface 14b is convex upward and a case in which the back surface 14b is convex downward.

FIG. 4 is a cross-sectional view taken along line B-B of FIG. 1.

As shown in FIG. 2, the upper side edge of the short side of the base plate 14, which is rectangular in a plan view, is flush with the support surface 14a. On the other hand, as shown in FIG. 4, a first inclined surface 24 is formed on the upper edge of the long side of the rectangular base plate 14 in a plan view. The first inclined surface 24 is inclined at an angle θ with respect to the support surface 14a. The angle θ is preferably, for example, 10° or more and 80° or less. The first inclined surface 24 is inclined toward the back surface 14b of the base plate 14 opposite to the support surface 14a in the normal direction to the support surface 14a as it goes outward. The first inclined surface 24 is connected to a first side surface 25 facing the outside of the base plate 14.

Furthermore, in the embodiment, when the center of each of the short and long sides of the rectangular base plate 14 in a plan view is taken as the center, the side toward the center in the direction along the support surface 14a is referred to as the inside. Further, the side away from the center in the direction along the support surface 14a is referred to as the outside.

The case 18 is provided around the base plate 14 and the circuit board 16. The case 18 surrounds the base plate 14 and the circuit board 16. The case 18 is an example of a frame. The case 18 has a function of protecting the first semiconductor element 10, the second semiconductor element 12, and the circuit board 16.

The case 18 has a rectangular outline when viewed in the normal direction. The case 18 is a square cylinder having a rectangular through hole 19 passing through in the normal direction when viewed in the normal direction. The case 18 has a rectangular outline and has a first side wall 18A which defines a short side and a second side wall 18B which defines a long side. As shown in FIG. 2, the lower end of the first side wall 18A is adhered to the support surface 14a of the base plate 14 at the adhesive region 20 in the normal direction.

As shown in FIG. 4, the lower end of the second side wall 18B has a second inclined surface 32 and a third inclined surface 33. The second inclined surface 32 is parallel to the first inclined surface 24 and faces the first inclined surface 24 in the normal direction. That is, the second inclined surface 32 is inclined at an angle θ with respect to the support surface 14a. The third inclined surface 33 is connected to the second inclined surface 32 and extends in a direction away from the first inclined surface 24. The third inclined surface 33 extends in an upward direction from the lower end of the second inclined surface 32 toward the outside. The third inclined surface 33 is connected to a second side surface 36 facing the outside of the second side wall 18B. In a cross section perpendicular to the support surface 14a, the second inclined surface 32 is longer than the third inclined surface 33. Since the second inclined surface 32 is longer than the third inclined surface 33, the bonding length with the first inclined surface 24 is increased, and the base plate 14 and the case 18 can be stably and adhesively fixed.

When the first inclined surface 24 and the second inclined surface 32 are joined in the normal direction, a concave portion (concave) 35 is formed between the base plate 14 and the case 18. In the concave portion 35, a space having a V-shaped cross section that opens to the outside and is surrounded by the first inclined surface 24 and the third inclined surface 33 is formed. In the concave portion 35, the first inclined surface 24 and the third inclined surface 33 are exposed.

The adhesive region 20 is a region where adhesive is applied to the base plate 14 and the case 18. The adhesive region 20 is provided at a position where the case 18 is adhered to the base plate 14 in the normal direction by an adhesive. That is, as shown by the dashed lines in FIG. 1, the adhesive region 20 has a first adhesive region 20A and a second adhesive region 20B.

The first adhesive region 20A of the adhesive region 20 is provided on the edge of the short side of the rectangular base plate 14 and the case 18. Specifically, as shown in FIG. 2, the first adhesive region 20A is provided on the lower end of the first side wall 18A and on the support surface 14a that faces the lower end of the first side wall 18A in the normal direction.

The second adhesive region 20B of the adhesive region 20 is provided on the edge of the long side of the rectangular base plate 14 and the case 18. Specifically, the second adhesive region 20B is provided on each of the first inclined surface 24 and the second inclined surface 32 as shown in FIG. 4.

The adhesive applied to the adhesive region 20 includes, for example, a resin. The adhesive includes, for example, silicone. The adhesive is, for example, a silicone resin. As the adhesive, it is also possible to use other resins such as an epoxy resin.

The adhesive is, for example, a thermosetting resin. The viscosity of the adhesive before curing is, for example, equal to or larger than 30 Pa·s and equal to or smaller than 1000 Pa·s. The viscosity of the adhesive before curing is, for example, equal to or larger than 30 Pa·s and smaller than 1000 Pa·s.

In the semiconductor device 100 of the embodiment, for example, the base plate 14 and the case 18 are fixed to each other by the adhesive region 20. In the semiconductor device 100, for example, as shown in FIG. 1, the base plate 14 and the case 18 may be fixed by fastening using a fastening member 17 in addition to the fixing by an adhesive in the adhesive region 20. Since the base plate 14 and the case 18 are fixed by fastening using the fastening member 17, the joint points between the first inclined surface 24 and the second inclined surface 32 are positioned apart in the short side direction. Accordingly, for example, it is possible to suppress problems in which the second inclined surface 32 shifts along the first inclined surface 24 and the case 18 tilts relative to the base plate 14.

The case 18 has a fitting protrusion 51B at the lower end of the first side wall 18A on the right side where the second power terminal 23 is disposed. As shown in FIG. 2, the fitting protrusion 51B protrudes downward from the first side wall 18A. The protruding length of the fitting protrusion 51B is shorter than the thickness of the base plate 14. As shown in FIG. 1, the fitting protrusion 51B is provided on the outer edge of the first side wall 18A. The fitting protrusions 51B are disposed on both sides of the substantially rectangular case 18 in the short side direction. Each fitting protrusion 51B is disposed between the hole 14c and the fastening member 17 in the short side direction. When viewed from above, each fitting protrusion 51B has a long semicircular shape obtained by halving an oval shape, having a major axis in the short side direction, in the short diameter direction.

Further, the case 18 has a fitting protrusion 52B at the lower end of the first side wall 18A on the left side where the first power terminal 22 is disposed. As shown in FIG. 2, the fitting protrusion 52B protrudes downward from the first side wall 18A. The protruding length of the fitting protrusion 52B is shorter than the thickness of the base plate 14. As shown in FIG. 1, the fitting protrusion 52B is provided on the outer edge of the first side wall 18A. The fitting protrusions 52B are disposed on both sides of the case 18 in the short side direction. Each fitting protrusion 52B is disposed between the hole 14c and the fastening member 17 in the short side direction. When viewed from above, each fitting protrusion 52B has a semicircular shape.

The base plate 14 is provided with fitting concave portions 51A at positions facing the two fitting protrusions 51B in the up and down direction. The fitting concave portion 51A penetrates the base plate 14 in the up and down direction. Each fitting concave portion 51A has an elongated semicircular shape when viewed from above. The fitting protrusion 51B is fitted into each of the fitting concave portions 51A from above.

Further, the base plate 14 is provided with fitting concave portions 52A at positions facing the two fitting protrusions 52B in the up and down direction. The fitting concave portion 52A penetrates the base plate 14 in the up and down direction. When viewed from above, each fitting concave portion 52A has a semicircular shape. The fitting protrusion 52B is fitted to each fitting concave portion 52A from above.

The fitting protrusion 51B of the case 18 and the fitting concave portion 51A of the base plate 14 are fitted to each other at two points on the right side, and the fitting protrusion 52B of the case 18 and the fitting concave portion 52A of the base plate 14 are fitted to each other on the left side, such that the case 18 and the base plate 14 are positioned in a direction perpendicular to the up and down direction. Further, since the fitting protrusion 51B and the fitting concave portion 51A have an elongated semicircular shape and the fitting protrusion 52B and the concave portion 52A have a semicircular shape, the concave portion and the convex portion cannot be fitted to each other at a position in which one of the case 18 and the base plate 14 is rotated by 180°, and thus incorrect assembly of the case 18 and the base plate 14 can be avoided.

The first power terminal 22 and the second power terminal 23 are provided on the upper portion of the first side wall 18A of the case 18. For example, a negative voltage is applied to the first power terminal 22. For example, a positive voltage is applied to the second power terminal 23.

The bonding wire 26 electrically connects, for example, between the first power terminal 22 and the first semiconductor element 10, between the metal layer of the circuit board 16 and the second semiconductor element 12, and between the metal layer of the circuit board 16 and the second power terminal 23. The bonding wire 26 is, for example, an aluminum wire.

The sealing resin 28 is filled in the case 18. The sealing resin 28 is surrounded by the case 18. The sealing resin 28 covers the first semiconductor element 10, the second semiconductor element 12, and the circuit board 16. The sealing resin 28 is an example of the sealing material. The sealing resin 28 has a function of protecting the first semiconductor element 10, the second semiconductor element 12, and the circuit board 16. Further, the sealing resin has a function of insulating the first semiconductor element 10, the second semiconductor element 12, and the circuit board 16.

The sealing resin 28 includes a resin. The sealing resin 28 is, for example, a silicone gel. The sealing resin 28 may be made of other resins such as epoxy resin, polyimide resin, or the like.

In the semiconductor device 100 with the above configuration, when the second adhesive region 20B is provided to be shifted inward (to the right in FIG. 4), the joint length between the first inclined surface 24 and the second inclined surface 32 is longer in a cross section perpendicular to the support surface than when the lower end is flush with the support surface 14a as in the first side wall 18A, so that air is less likely to reach the sealing material 28.

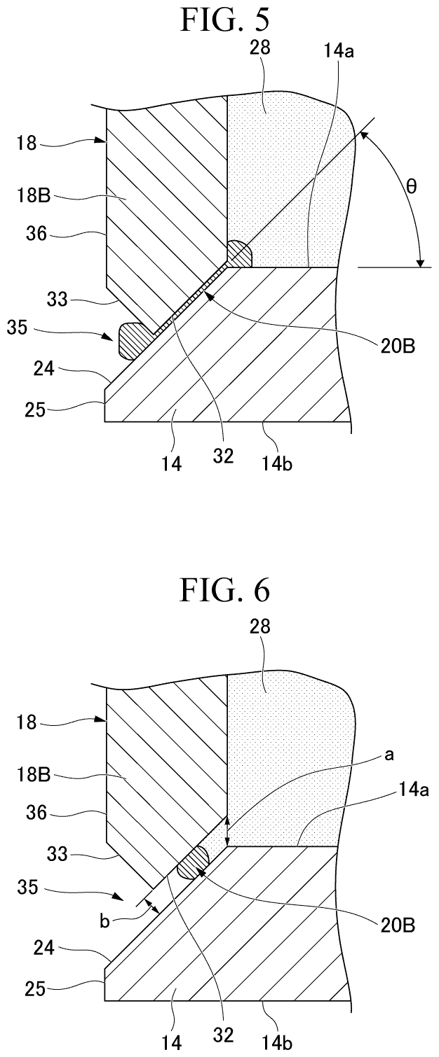

Further, as shown in FIG. 5, if the second adhesive region 20B is provided to be shifted outward (to the left in FIG. 5), there is a possibility that the adhesive may overflow from the intersection between the second inclined surface 32 and the third inclined surface 33. At this time, since the concave portion 35 surrounded by the first inclined surface 24 and the third inclined surface 33 is formed between the base plate 14 and the case 18, the overflowing adhesive is contained in the concave portion 35 and is suppressed from overflowing outward beyond the first side surface 25 and the second side surface 36.

Here, since the third inclined surface 33 extends upward as it goes outward from the lower end of the second inclined surface 32, the cross-sectional area of the concave portion 35 is wider than when the third inclined surface 33 extends outward from the lower end of the second inclined surface 32 in parallel to the support surface 14a. Therefore, the amount of overflowing adhesive that can be accommodated is increased, and the adhesive is further suppressed from overflowing outward beyond the first side surface 25 and the second side surface 36.

Moreover, since the adhesive that has overflowed into the concave portion 35 comes into contact with both the first inclined surface 24 and the third inclined surface 33 due to surface tension, the position of the outer tip of the adhesive is on the inside compared to the case where the adhesive is in contact only with the first inclined surface 24, and the adhesive is further suppressed from overflowing outward beyond the first side surface 25 and the second side surface 36.

Further, as described above, the end of the base plate 14 is curved downward with respect to the center. Therefore, since a gap between the base plate 14 and the case 18 in the normal direction becomes large when they are adhered to each other as shown in FIG. 6, there is a possibility that the adhesive applied to the second adhesive region 20B may not be able to fill the gap between the base plate 14 and the case 18. In this case, since air may enter the unfilled gap, there is a possibility that the above problems may occur. There is also a risk that the sealing material 28 may leak through the gap.

In the embodiment, in order to join the first inclined surface 24 and the second inclined surface 32, the gap dimension b between the first inclined surface 24 and the second inclined surface 32 with respect to the gap dimension a between the base plate 14 and the case 18 in the normal direction at the time of adhering becomes a×cosθ, and becomes smaller than the gap dimension a. For example, when the angle θ is 45°, the gap dimension b can be reduced to approximately 70% of the gap dimension a.

Thus, in the embodiment, since the first inclined surface 24 and the second inclined surface 32 are joined to each other, the gap dimension b between the first inclined surface 24 and the second inclined surface 32 is smaller than when the lower end is flush with the support surface 14a as in the first side wall 18A. Accordingly, it is possible to suppress problems caused by air entering unfilled gaps. Further, since the gap dimension b decreases, it is possible to reduce the risk that the sealing material 28 may leak from the gap between the first inclined surface 24 and the second inclined surface 32.

Further, a high viscous adhesive is often used to ensure a sufficient thickness to fill the gap in consideration of the size of the gap dimension a. The high viscous adhesive can ensure thickness, but the adhesive strength is relatively weaker than the low viscous adhesive. Therefore, in the semiconductor device 100, a material that is less likely to warp due to heating is often selected for the base plate 14. In the embodiment, since the gap dimension b decreases, it is possible to use an adhesive with low viscosity and high adhesive strength, and it is possible to suppress the adhesive from peeling off due to expansion and contraction of the adhesive caused by heat after the base plate 14 and the case 18 are adhered together. Further, it is possible to use materials such as copper, which has a relatively large warp but has high thermal conductivity and excellent cooling efficiency.

According to any one of the above-described embodiments, since the base plate 14 has the first inclined surface 24, the case 18 has the second inclined surface 32 facing the first inclined surface 24, the adhesive region 20 is provided in each of the first inclined surface 24 and the second inclined surface 32, and the concave portion 35 is formed between the base plate 14 and the case 18 to expose at least one of the first inclined surface 24 and the second inclined surface 32, it is possible to suppress the adhesive from overflowing outward and to suppress the air having entered the gap from reaching the sealing material 28 even if the adhesive region 20 is shifted. As a result, it is possible to improve the adhesion between the case 18 and the base plate 14.

Further, according to any one embodiment, since the gap dimension b between the first inclined surface 24 and the second inclined surface 32 can be smaller than the gap dimension a in the normal direction, it is possible to suppress problems caused by air having entered the gap and to use an adhesive with low viscosity and strong adhesive strength. As a result, materials such as copper, which has high thermal conductivity and excellent cooling efficiency, can be used, and versatility can be improved.

### Second Embodiment of Semiconductor Device

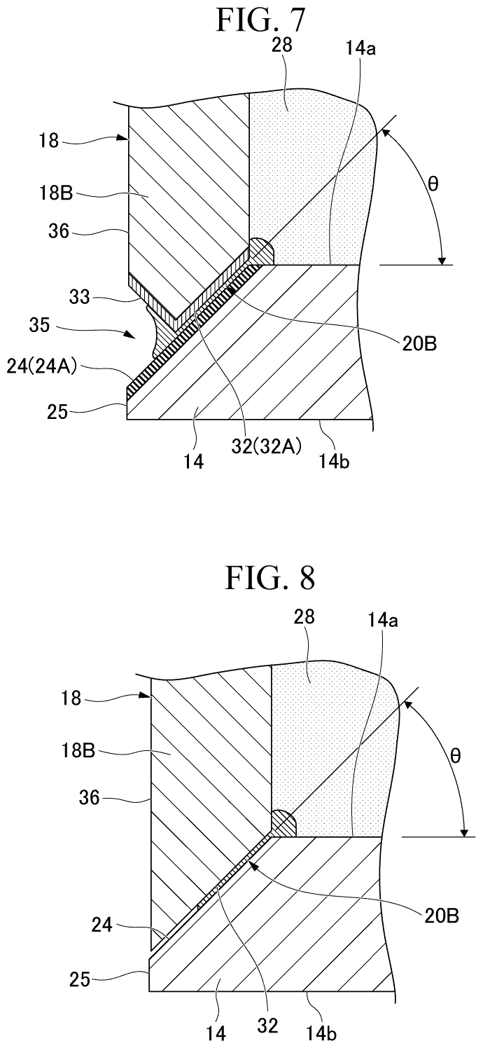

Next, a second embodiment of the semiconductor device 100 will be described with reference to FIG. 7.

In this figure, the same components as those in the first embodiment shown in FIGS. 1 to 6 are denoted by the same reference numerals, and the description thereof will be omitted.

FIG. 7 is a partially cross-sectional view showing the semiconductor device 100 of the second embodiment.

As shown in FIG. 7, the base plate 14 has a first roughened portion 24A in which the surface of the first inclined surface 24 is roughened. The case 18 has a second roughened portion 32A in which the second inclined surface 32 and the third inclined surface 33 are roughened. The first roughened portion 24A and the second roughened portion 32A have a surface roughness larger than that of the support surface 14a. The surface roughness of the first roughened portion 24A and the second roughened portion 32A is preferably equal to or larger than Ra 10. Examples of the roughening treatment include chemical treatment such as etching and physical treatment such as sandblasting.

The other configurations are similar to those of the first embodiment.

In the semiconductor device 100 with the above configuration, since the first roughened portion 24A and the second roughened portion 32A are provided, the first inclined surface 24 and the second inclined surface 32 have large surface areas. Therefore, the adhesive strength of the adhesive is increased on the first inclined surface 24 and the second inclined surface 32. Therefore, peeling of the adhesive due to expansion and contraction of the adhesive caused by heat after adhering can be further suppressed.

Further, in the semiconductor device 100 with the above configuration, since the adhesive having overflowed into the concave portion 35 from the intersection between the first inclined surface 24 and the third inclined surface 33 extends along the first inclined surface 24 and the third inclined surface 33 in the first roughened portion 24A and the second roughened portion 32A due to capillary action, the surface exposed to the outside becomes concave. Therefore, the adhesive having overflowed into the concave portion 35 can be further suppressed from overflowing outward.

According to any one embodiment, in addition to the operations and effects as in the first embodiment, it is possible to further suppress peeling of the adhesive and to suppress the adhesive having overflowed into the concave portion 35 from overflowing outward by increasing the adhesive strength of the adhesive on the first inclined surface 24 and the second inclined surface 32.

### Third Embodiment of Semiconductor Device

Next, a third embodiment of the semiconductor device 100 will be described with reference to FIG. 8.

In this figure, the same components as those in the first embodiment shown in FIGS. 1 to 6 are denoted by the same reference numerals, and the description thereof will be omitted.

FIG. 8 is a partially cross-sectional view showing the semiconductor device 100 of the third embodiment.

As shown in FIG. 8, the first inclined surface 24 is connected to the first side surface 25 that faces the outside of the base plate 14. The second inclined surface 32 is connected to the second side surface 36 that faces the outside of the case 18. The case 18 does not have the third inclined surface 33. Thus, the semiconductor device 100 does not include the concave portion 35.

The other configurations are similar to those of the first embodiment.

According to any one embodiment, in addition to the operations and effects as in the first embodiment except for the operations and effects of the third inclined surface 33 and the concave portion 35, compared to when the lower end is flush with the support surface 14a as in the first side wall 18A, the length of the first inclined surface 24 and the second inclined surface 32 can be increased by approximately 1.7 times, and even if the position of the adhesive region 20 is shifted, the adhesive can be further suppressed from overflowing outward.

### Fourth Embodiment of Semiconductor Device

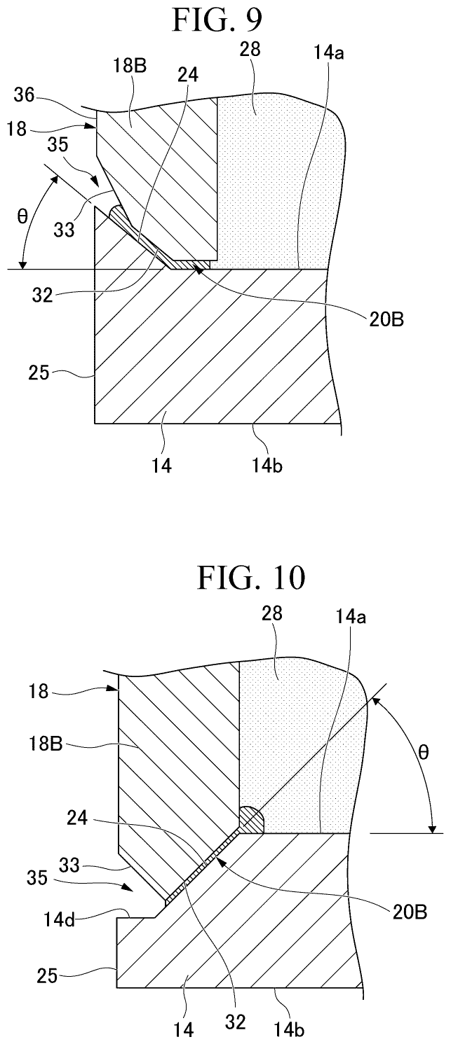

Next, a fourth embodiment of the semiconductor device 100 will be described with reference to FIG. 9.

In this figure, the same components as those in the first embodiment shown in FIGS. 1 to 6 are denoted by the same reference numerals, and the description thereof will be omitted.

FIG. 9 is a partially cross-sectional view showing the semiconductor device 100 of the fourth embodiment.

In the above embodiments, although a configuration has been described in which the first inclined surface 24 and the second inclined surface 32 are inclined with respect to the support surface 14a toward the back surface 14b (lower side) opposite to the support surface 14a of the base plate 14 as it goes outward, the present invention is not limited to this configuration.

As shown in FIG. 9, the first inclined surface 24 and the second inclined surface 32 of the semiconductor device 100 of the fourth embodiment are inclined upward at an angle θ as it goes outward. The third inclined surface 33 is inclined upward at an angle larger than the angle θ from the upper end of the second inclined surface 32 as it goes outward. The inner space of the concave portion 35 extends upward as it goes outward.

The other configurations are similar to those of the first embodiment.

According to any one embodiment, in addition to the operations and effects as in the first embodiment, since the opening of the concave portion 35 is located above the inner space, the adhesive having entered the concave portion 35 can be suppressed from overflowing outward beyond the first side surface 25 and the second side surface 36 due to the own weight.

### Fifth Embodiment of Semiconductor Device

Next, a fifth embodiment of the semiconductor device 100 will be described with reference to FIG. 10.

In this figure, the same components as those in the first embodiment shown in FIGS. 1 to 6 are denoted by the same reference numerals, and the description thereof will be omitted.

FIG. 10 is a partially cross-sectional view showing the semiconductor device 100 of the fifth embodiment.

As shown in FIG. 10, the base plate 14 has an upper surface 14d on the outside of the first inclined surface 24. The upper surface 14d is parallel to the support surface 14a and is located below the support surface 14a. The upper surface 14d is connected to the first side surface 25.

The first inclined surface 24 is connected to the upper surface 14d on the outside. In the concave portion 35, a space surrounded by the first inclined surface 24, the third inclined surface 33, and the upper surface 14d and opening to the outside is formed. In the concave portion 35, the first inclined surface 24, the third inclined surface 33, and the upper surface 14d are exposed.

According to any one embodiment, in addition to the operations and effects as in the first embodiment, since the upper surface 14d exposed to the inner space of the concave portion 35 and located on the lower side is parallel to the support surface 14a and does not extend downward as it goes outward, the adhesive having entered the concave portion 35 can be suppressed from overflowing outward beyond the first side surface 25 and the second side surface 36 due to the own weight.

By adopting a configuration in which the upper surface 14d is extended upward as it goes outward, it is possible to further suppress the adhesive having entered the concave portion 35 from overflowing outward beyond the first side surface 25 and the second side surface 36 due to the own weight.

Furthermore, in the above embodiments, although a configuration has been described in which the first inclined surface 24 and the second inclined surface 32 are provided in the second adhesive region 20B on the edge of the long side of the rectangular base plate 14 and case 18, the first and second inclined surfaces may be also provided in the first adhesive region 20A on the edge of the short side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a circuit board on which a semiconductor element is mounted;
a base plate which supports the circuit board on a support surface; and
a case which is adhered to the base plate at an adhesive region in a normal direction of the support surface and surrounds the circuit board,
wherein the base plate has a first inclined surface which is inclined with respect to the support surface,
wherein the case has a second inclined surface which is parallel to the first inclined surface and faces the first inclined surface in the normal direction,
wherein the adhesive region is provided in each of the first inclined surface and the second inclined surface, and
wherein a concave opens to the outside between the base plate and the case and exposes at least one of the first inclined surface and the second inclined surface.

2. The semiconductor device according to claim 1,
wherein the first inclined surface and the second inclined surface are inclined in the normal direction to the support surface toward a back surface of the base plate opposite to the support surface as they go outward.

3. The semiconductor device according to claim 1,
wherein the first inclined surface and the second inclined surface have a surface roughness larger than that of the support surface.

4. The semiconductor device according to claim 1,
wherein the case has a third inclined surface which is connected to the second inclined surface and extends in a direction away from the first inclined surface.

5. The semiconductor device according to claim 4,
wherein the second inclined surface is longer than the third inclined surface in a cross section perpendicular to the support surface.

6. The semiconductor device according to claim 4,
wherein the third inclined surface has a surface roughness larger than that of the support surface.

7. The semiconductor device according to claim 1,
wherein the base plate and the case are rectangular when viewed in the normal direction, and
wherein the first inclined surface and the second inclined surface are respectively provided on edges of long sides of the base plate and the case.

8. A semiconductor device comprising:
a circuit board on which a semiconductor element is mounted;
a base plate which supports the circuit board on a support surface; and
a case which is adhered to the base plate at an adhesive region in a normal direction of the support surface and surrounds the circuit board,
wherein the base plate has a first inclined surface which is inclined with respect to the support surface,
wherein the case has a second inclined surface which faces the first inclined surface in parallel in the normal direction,
wherein the adhesive region is provided in each of the first inclined surface and the second inclined surface,
wherein the first inclined surface is connected to a first side surface that faces the outside of the base plate, and
wherein the second inclined surface is connected to a second side surface that faces the outside of the case.
